(19) United States
(12) Patent Application Publication
(10) Pub. No.: US 2014/0091444 A1
(43) Pub. Date: Apr. 3, 2014

(54) SEMICONDUCTOR UNIT AND METHOD FOR MANUFACTURING THE SAME

(71) Applicant: KABUSHIKI KAISHA TOYOTA JIDOSHOKKI, Kariya-shi (JP)

(72) Inventors: Shogo MORI, Aichi-ken (JP); Yuri OTOBE, Aichi-ken (JP); Naoki KATO, Aichi-ken (JP); Shinsuke NISHI, Aichi-ken (JP)

(73) Assignee: KABUSHIKI KAISHA TOYOTA JIDOSHOKKI, Kariya-shi (JP)

(21) Appl. No.: 14/032,690

(22) Filed: Sep. 20, 2013

(30) Foreign Application Priority Data
Sep. 28, 2012 (JP) 2012-216361

(51) Int. Cl. H01L 23/00; H01L 21/50

(52) U.S. Cl. CPC H01L 23/562; H01L 21/50
USPC 257/669; 438/121

(57) ABSTRACT

A semiconductor unit includes a base, an insulating substrate bonded to the base, a conductive plate made of a metal of poor solderability, a semiconductor device mounted to the insulating substrate through the conductive plate, and a metal plate interposed between the conductive plate and the semiconductor device and made of a metal of good solderability as compared to the metal used for the conductive plate. The base, the insulating substrate, the conductive plate and the metal plate are brazed together, and the semiconductor device is soldered to the metal plate.

### BACKGROUND OF THE INVENTION

The present invention relates to a semiconductor unit in which a semiconductor device is mounted to an insulating substrate through a metal conductive plate of poor solderability, and also to a method for manufacturing the semiconductor unit.

There has been known a semiconductor unit in which a semiconductor device is mounted to an insulating substrate made of a material such as aluminum nitride with an aluminum conductive plate interposed therebetween. In such semiconductor unit, soldering of the semiconductor device to the aluminum conductive plate is difficult due to poor solderability or wetting of aluminum. To solve this problem, there has been proposed a method of forming a nickel (Ni) layer on an aluminum conductive plate by plating and then soldering a semiconductor device to the Ni plating layer, as disclosed in Japanese Unexamined Patent Application Publication No. 2010-238932.

In the above semiconductor unit having the plating layer between the conductive plate and the semiconductor device, increasing the bonding strength between the conductive plate and the semiconductor device requires increasing the bonding strength between the conductive plate and the plating layer. However, the strength of bonding between the plating layer and the conductive plate is limited even if the kind of plating material is changed, which means that it is difficult to further increase the bonding strength between the conductive plate and the semiconductor device and hence to increase the reliability of the semiconductor unit.

The present invention is directed to providing a semiconductor unit of a structure that allows increased bonding strength between the metal conductive plate of poor solderability and the semiconductor device and hence allows increased reliability of the unit, and also to providing a method for manufacturing the semiconductor unit.

### SUMMARY OF THE INVENTION

In accordance with an aspect of the present invention, a semiconductor unit includes a base, an insulating substrate bonded to the base, a conductive plate made of a metal of poor solderability, a semiconductor device mounted to the insulating substrate through the conductive plate, and a metal plate interposed between the conductive plate and the semiconductor device and made of a metal of good solderability as compared to the metal used for the conductive plate. The base, the insulating substrate, the conductive plate and the metal plate are brazed together, and the semiconductor device is soldered to the metal plate.

Other aspects and advantages of the invention will become apparent from the following description, taken in conjunction with the accompanying drawings, illustrating by way of example the principles of the invention.

### BRIEF DESCRIPTION OF THE DRAWINGS

FIG. 1A is a sectional view of a semiconductor unit according to a first embodiment of the present invention;

FIG. 1B is a top view of the semiconductor unit of FIG. 1A;

FIG. 2 shows diagrams explaining a process of manufacturing the semiconductor unit of FIGS. 1A and 1B; and

FIG. 3 is a sectional view of another embodiment of the semiconductor unit according to the present invention.

### DETAILED DESCRIPTION OF THE EMBODIMENTS

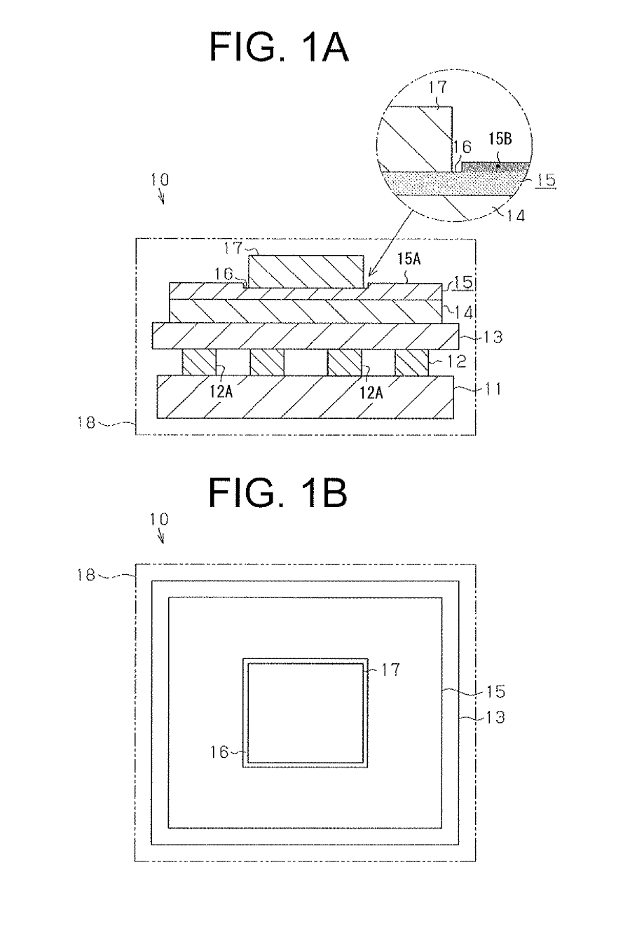

The following will describe one embodiment of the semiconductor unit according to the present invention with reference to the accompanying drawings. Referring to FIG. 1A, the semiconductor unit of the present embodiment which is designated generally by 10 includes a heat sink 11 as the base of the semiconductor unit 10, a stress relief member 12 bonded to the top surface of the heat sink 11 by brazing, and an insulating substrate 13 bonded to the top surface of the stress relief member 12 by brazing.

The stress relief member 12 is in the form of a rectangular plate and has plural holes 12A formed therethrough in the direction of its thickness. The hole 12A allows deformation of the stress relief member 12 and serves to reduce the thermal stress occurring in the stress relief member 12. The insulating substrate 13 may be provided by a ceramic substrate made of, for example, aluminum oxide, silicon nitride, silicon carbide, aluminum nitride, or alumina zirconium.

The semiconductor unit 10 further includes a conductive plate 14 brazed to the top surface of the insulating substrate 13 and a metal plate 15 brazed to the top surface of the conductive plate 14. The conductive plate 14 is made of a metal of poor solderability, and the metal plate 15 is made of a metal of good solderability as compared to the metal used for the conductive plate 14. The metal plate 15 has almost the same profile as the conductive plate 14 in top view and covers the entire top surface of the conductive plate 14.

The metal of poor solderability used for the conductive plate 14 is, for example, aluminum or aluminum alloy. The metal of good solderability used for the metal plate 15 is, for example, nickel, nickel alloy, copper or copper alloy.

As shown in the insert of FIG. 1A, there exists an oxide layer 15B at the top surface 15A of the metal plate 15. The oxide layer 15B is made of metal oxide formed by surface oxidation. Part of the oxide layer 15B is mechanically removed to form a recess 16 in the top surface 15A of the metal plate 15. The recess 16 where the oxide layer 15B is removed has a small metal oxide ratio as compared to the part of the top surface 15A of the metal plate 15 other than the recess 16. As shown in FIG. 1B, the recess 16 has a slightly larger profile than the semiconductor device 17. In the present embodiment, the semiconductor device 17 is bonded to the top surface 15A of the metal plate 15.

Although not shown in the drawing, the semiconductor device 17 is equipped with various terminals which are to be electrically connected, for example, to an external terminal by means such as wire. In the present embodiment, the entire of the semiconductor unit 10 except the part for electrical connection to the external terminal is molded by a sealing resin 18 into a module.

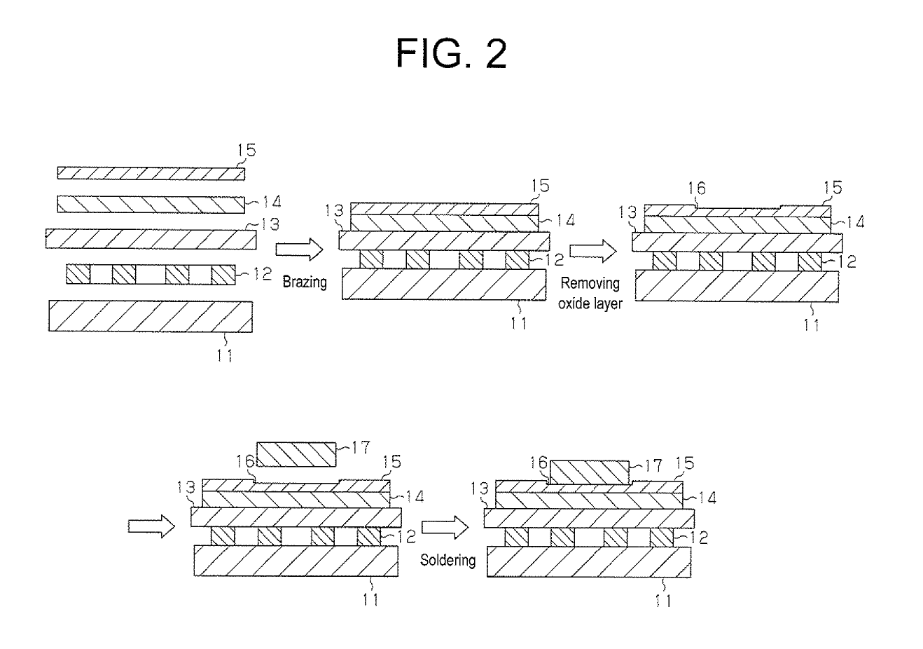

The following will describe a process of manufacturing the semiconductor unit 10 of the present embodiment with reference to FIG. 2. The semiconductor unit 10 is manufactured through the steps of brazing, removing oxide layer and then soldering.

In the step of brazing, the heat sink 11, the stress relief member 12, the insulating substrate 13, the conductive plate 14 and the metal plate 15 are brazed together. Specifically, firstly, the heat sink 11, the stress relief member 12, the insulating substrate 13, the conductive plate 14 and the metal plate 15 are stacked with a brazing metal in the form of a sheet (not shown) interposed between any two adjacent components. After heating the stack to melt the brazing metal between the components, the molten brazing metal is cooled and solidified, so that the heat sink 11, the stress relief member 12, the insulating substrate 13, the conductive plate 14 and the metal plate 15 are brazed together at one time.

During the step of brazing to melt the brazing metal, the metal plate 15 is exposed to high temperature environment, so that an oxide layer 15B (see FIG. 1A) is formed by surface oxidation at the top surface 15A of the metal plate 15. In the next step of removing oxide layer, the oxide layer 15B is removed to form the aforementioned recess 16 in the top surface 15A of the metal plate 15. Specifically, the part of the oxide layer 15B of the top surface 15A of the metal plate 15 where the semiconductor device 17 is to be bonded is mechanically removed so that the recess 16 is formed in the top surface 15A of the metal plate 15.

In the next step of soldering, the semiconductor device 17 is soldered to the metal plate 15 of the stack. Specifically, firstly, the semiconductor device 17 is set in the recess 16 in the top surface 15A of the metal plate 15 with a solder sheet (not shown) placed between the semiconductor device 17 and the surface of the recess 16. After heating the stack to melt the solder, the molten solder is cooled and solidified, so that the semiconductor device 17 is bonded to the metal plate 15. The recess 16 of the metal plate 15 where the oxide layer 15B is removed has a small metal oxide ratio and provides good wetting for solder, which allows good solder bonding between the metal plate 15 and the semiconductor device 17.

After the completion of the soldering, various terminals of the semiconductor device 17 are electrically connected to the external terminal by means such as wire. Then the entire of the semiconductor unit 10 is molded by the sealing resin 18 into a power module.

In the above-described semiconductor unit 10, the metal plate 15 of good solderability is interposed between the conductive plate 14 of poor solderability and the semiconductor device 17. The conductive plate 14 and the metal plate 15 are brazed together and then the metal plate 15 and the semiconductor device 17 are soldered together, so that the conductive plate 14 and the semiconductor device 17 are bonded together.

The bonding between the conductive plate 14 and the metal plate 15 by brazing has a higher strength than the bonding between the conductive plate and the plating layer where the semiconductor device is soldered as in the conventional case, which results in increased bonding strength between the conductive plate 14 and the semiconductor device 17 and hence in increased mechanical strength and reliability of the semiconductor unit 10.

The semiconductor unit 10 of the present embodiment offers the following advantages.

(1) The semiconductor unit 10 includes the metal plate 15 of good solderability between the conductive plate 14 of poor solderability and the semiconductor device 17. The conductive plate 14 and the metal plate 15 are bonded together by brazing. The metal plate 15 and the semiconductor device 17 are bonded together by soldering. This results in increased mechanical strength and reliability of the semiconductor unit 10.

(2) The semiconductor device 17 is soldered to the recess 16 of the metal plate 15 where part of the oxide layer 15B formed at the top surface 15A of the metal plate 15 is mechanically removed. The recess 16 has a smaller metal oxide ratio than other part of the top surface 15A of the metal plate 15 and hence provides good wetting for solder. This allows good solder bonding of the semiconductor device 17 to the recess 16 of the metal plate 15, resulting in increased bonding strength between the metal plate 15 and the semiconductor device 17.

(3) The recess 16 is formed by mechanically removing part of the oxide layer 15B at the top surface 15A of the metal plate 15. The recess 16 thus formed functions as a solder holding portion which prevents solder from flowing over the metal plate 15 from the recess 16 during the soldering operation and also helps to keep solder remaining between the semiconductor device 17 and the metal plate 15, thereby resulting in increased solder bonding strength between the semiconductor device 17 and the metal plate 15

(4) The stress relief member 12 having the plural holes 12A is disposed between the heat sink 11 and the insulating substrate 13. The stress relief member 12 serves to reduce the thermal stress caused by the difference in the coefficient of linear expansion between the metal plate 15 and the conductive plate 14.

(5) The use of the heat sink 11 as the base of the semiconductor unit 10 allows efficient radiation of the heat generated in the semiconductor device 17 from the heat sink 11 and hence efficient cooling of the semiconductor device 17.

(6) The method of manufacturing the semiconductor unit 10 includes the step of brazing the heat sink 11, the stress relief member 12, the insulating substrate 13, the conductive plate 14 and the metal plate 15 together, and the step of soldering the semiconductor device 17 to the metal plate 15. Such method provides a semiconductor unit of high bonding strength between the conductive plate 14 and the semiconductor device 17. In addition, unlike the conventional case, the method according to the present invention requires no process of plating on the conductive plate and hence no equipment therefor, resulting in reduced manufacturing cost.

(7) In the step of brazing, the heat sink 11, the stress relief member 12, insulating substrate 13, the conductive plate 14 and the metal plate 15 are brazed together at one time. This results in reduced number of operations during the brazing and further reduced manufacturing cost.

(8) The method of manufacturing the semiconductor unit 10 includes the step of removing the oxide layer 15B at the top surface 15A of the metal plate 15 after the step of brazing. The part of the top surface 15A of the metal plate 15 where the oxide layer 15B is removed provides good wetting for solder, allowing good bonding between the metal plate 15 and the semiconductor device 17 in the subsequent step of soldering.

The above embodiment may be modified in various ways as exemplified below.

Although the recess 16 should preferably be formed in such a manner that the oxide layer 15B is entirely removed, there may exist a little metal oxide remaining in the recess 16.

The recess 16 may be formed at any suitable position. The recess 16 may be formed locally in the top surface 15A of the metal plate 15 only at a position where the semiconductor device 17 is bonded, or alternatively may be formed entirely over the top surface 15A of the metal plate 15.

The recess 16 may be of any suitable profile. When plural semiconductor devices such as 17 are bonded to the metal plate 15, there may be provided plural recesses having profiles corresponding to the respective semiconductor devices, or alternatively there may be provided one recess having a profile that is large enough for the bonding of the plural semiconductor devices. When the recess 16 is made to function as the solder holding portion, the recess 16 should preferably be formed locally in such a manner that the profile of the recess 16 is the same as or slightly larger than the profile of the semiconductor device 17.

In the forming of the recess 16, the oxide layer 15B at the top surface 15A of the metal plate 15 may not only be removed mechanically, but also removed by chemical reduction using means such as chemicals. Also in the step of removing oxide layer in the method of manufacturing the semiconductor unit 10, the oxide layer 15B may not only be removed mechanically, but also removed by chemical reduction.

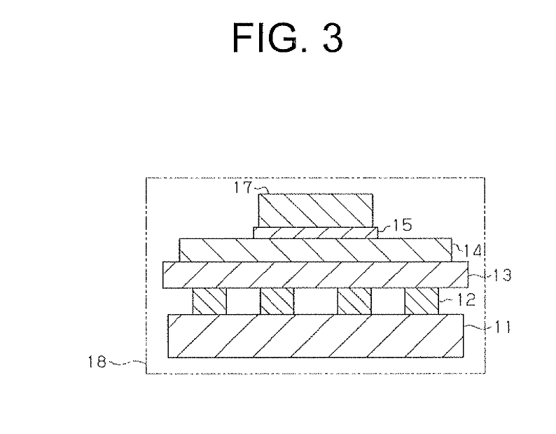

Although in the illustrated embodiment the metal plate 15 is disposed over the entire top surface of the conductive plate 14, the metal plate 15 may be disposed only on the part of the top surface of the conductive plate 14 where the semiconductor device 17 is mounted. For example, as shown in FIG. 3, the metal plate 15 may be disposed on the conductive plate 14 only at a region where the conductive plate 14 overlaps the semiconductor device 17, as seen in the stacked direction of the conductive plate 14, the metal plate 15 and the semiconductor device 17.

Such arrangement of the metal plate 15 helps to reduce the size of the metal plate 15 and the amount of bonding material, such as solder or brazing metal, used for the bonding of the metal plate 15 to other components, resulting in further reduced manufacturing cost of the semiconductor unit 10. The metal plate 15 of such a small size allows the top surface of the conductive plate 14 to have a region that is not in contact with the metal plate 15, thereby allowing reduction of the thermal stress caused by the difference in the coefficient of linear expansion between the metal plate 15 and the conductive plate 14. In the case of FIG. 3, the oxide layer 15B should preferably be removed entirely over the top surface of the metal plate 15.

There may be provided additional members such as a metal plate between the heat sink 11 and the stress relief member 12, between the stress relief member 12 and the insulating substrate 13, and between the insulating substrate 13 and the conductive plate 14. The semiconductor unit 10 need not necessarily include the stress relief member 12. The heat sink 11 may be replaced by any other suitable member serving as the base of the semiconductor unit 10 of the present invention but having no cooling function.

The manner of molding by the sealing resin 18 may be changed. Although in the illustrated embodiment the sealing resin 18 covers the heat sink 11 entirely, the sealing resin 18 may cover the top surface of the heat sink 11 and the components mounted thereon or alternatively may cover the insulating substrate 13 and the components mounted thereon so that part of the heat sink 11 is exposed out of the sealing resin 18.

In the step of brazing in the method of manufacturing the semiconductor unit 10, the components need not necessarily be brazed at one time, but may bₑ brazed in sequence.

The method of manufacturing the semiconductor unit 10 need not necessarily include the step of removing oxide layer.

In the steps of brazing and soldering, the bonding of the components of the semiconductor unit may be done by any known method, using any known brazing metal and solder.

What is claimed is:

1. A semiconductor unit, comprising:
a base;
an insulating substrate bonded to the base;
a conductive plate made of a metal of poor solderability;
a semiconductor device mounted to the insulating substrate through the conductive plate; and
a metal plate interposed between the conductive plate and the semiconductor device and made of a metal of good solderability as compared to the metal used for the conductive plate,
wherein the base, the insulating substrate, the conductive plate and the metal plate are brazed together, and the semiconductor device is soldered to the metal plate.

2. The semiconductor unit of claim 1, wherein the metal plate has a solder holding portion where the semiconductor device is bonded.

3. The semiconductor unit of claim 2, wherein part of an oxide layer formed on the metal plate during the brazing is removed to form a recess that serves as the solder holding portion.

4. The semiconductor unit of claim 1, wherein the metal plate is disposed only on the part of the conductive plate where the semiconductor device is mounted.

5. The semiconductor unit of claim 1, further comprising a stress relief member between the base and the insulating substrate.

6. The semiconductor unit of claim 1, wherein the base is a heat sink.

7. A method for manufacturing the semiconductor unit of claim 1, comprising the steps of:
brazing the base, the insulating substrate, the conductive plate and the metal plate together; and
soldering the semiconductor device to the metal plate.

8. The method of claim 7, wherein the base, the insulating substrate, the conductive plate and the metal plate are brazed together at one time.

9. The method of claim 7, further comprising the step of removing an oxide layer that is formed on the metal plate during the brazing,
wherein the semiconductor device is soldered to the part of the metal plate where the oxide layer is removed.
